(19) United States
(12) Patent Application Publication
(10) Pub. No.: US 2011/0316725 A1
(43) Pub. Date: Dec. 29, 2011

(54) SCANNING CIRCUIT AND METHOD FOR KEYBOARD

(75) Inventors: YAN XU, Shenzhen City (CN); YONG-YONG LI, Shenzhen City (CN); HUI YIN, Shenzhen City (CN); BO-CHING LIN, Taipei Hsien (TW)

(73) Assignees: HON HAI PRECISION INDUSTRY CO., LTD., Taipei Hsien (TW); HONG FU JIN PRECISION INDUSTRY (ShenZhen) CO., LTD., Shenzhen City (CN)

(21) Appl. No.: 12/962,609

(22) Filed: Dec. 7, 2010

(30) Foreign Application Priority Data
Jun. 24, 2010 (CN) 201010208971.7

(51) Int. Cl. H03K 17/94

(52) U.S. Cl. 341/26

(57) ABSTRACT

A scanning circuit includes n column wires, a ground column wire, n row wires, n*n keys, and n diodes. The column wires and the ground column wire cross the n row wires to form n*(n+1) intersections. The ground column wire having a terminal is for being connected to the high voltage source and the other terminal is grounded. A control unit includes n ports electrically connected to the row wires correspondingly. The diodes are set on n intersections of the matrix, and each diode has a positive terminal electrically connected to the corresponding row wire, and a negative terminal electrically connected to the corresponding numbered column wire. The n*n keys are set on the intersections except where the diodes are located, the n*n keys are connected across column wires, the ground column wire, and the n row wires correspondingly. A related method is also provided.

### BACKGROUND

1. Technical Field

The present disclosure relates to scanning circuits and scanning methods for keyboards, and particularly, to a scanning circuit and a scanning method employed in a matrix keyboard.

2. Description of the Related Art

Keyboards are widely used as input means for various electronic devices, such as computers and personal digital assistants (PDAs). Usually, each keyboard includes a plurality of keys capable of being pressed, and a scanning circuit with a row-column type wiring structure aligned with the keys. The keys are set above the intersections where the row wires cross the column wires. A plurality of switches is deposited at the intersections, with two contacts of each switch being electrically connected to one row wire and one column wire respectively. Therefore, when a key is pressed, the corresponding switch is closed by the key. The row wire and the column wire corresponding to this switch are then electrically connected together. When the scanning circuit works, the column wires are connected to output ports of a single-chip microprocessor and are set by the single-chip microprocessor to be either high or low, and the row wires are connected to input ports of the single-chip microprocessor. During scanning, each output port is sequentially set low by the single-chip microprocessor. When one of the output ports is set low, the rest of the output ports are set high. The input ports are checked to find out if any switches are closed, so as to check whether any key is pressed down.

However, such a scanning circuit occupies too many ports of a microprocessor.

Therefore, a scanning circuit and a scanning method using fewer ports are needed in the industry.

### BRIEF DESCRIPTION OF THE DRAWINGS

The components in the drawings are not necessarily drawn to scale, the emphasis instead being placed upon clearly illustrating the principles of scanning circuit and method for keyboard. Moreover, in the drawings, like reference numerals designate corresponding parts throughout the several views.

FIG. 1 is a schematic diagram of a scanning circuit in accordance with an exemplary embodiment.

FIG. 2 is a scanning sequence diagram of the scanning circuit of FIG. 1.

FIG. 3 is a truth table for the ports of the scanning circuit of FIG. 1.

FIG. 4 is a flowchart of a scanning method in accordance with an exemplary embodiment.

### DETAILED DESCRIPTION

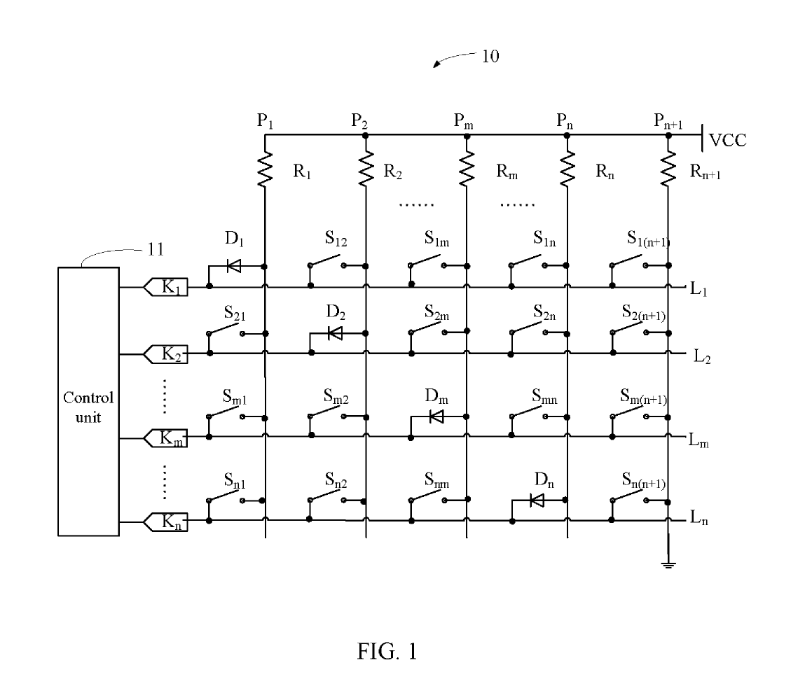

Referring to FIG. 1, a scanning circuit 10 in accordance with an exemplary embodiment is illustrated. The scanning circuit 10 includes n row wires L₁˜Lₙ and (n+1) column wires P₁˜Pₙ₊₁, where n is a natural number. The row wires L₁˜Lₙ, and the column wires P₁˜Pₙ form a matrix keyboard (not labeled), which includes n*(n+1) intersections. The scanning circuit 10 further includes n*n keys S₁₂˜Sₙ₍ₙ₊₁) and n diodes D₁˜Dₙ deposited at the intersections. Each diode has a positive terminal electrically connected to the corresponding row wire, and a negative terminal electrically connected to the corresponding numbered column wire.

The column wires P₁˜Pₙ₊₁ are each electrically connected to a power supply VCC via a resistor. The column wire Pₙ₊₁ is also grounded.

The row wires L₁˜Lₙ are electrically connected to n ports K₁˜Kₙ, correspondingly. The ports K₁˜Kₙ are I/O ports of a control unit 11 such as a single-chip microprocessor (not shown). The n*n keys S₁₍ₙ₊₁₎˜Sₙ₍ₙ₊₁₎ are located at the intersections except those where the diodes D₁˜Dₙ are located, the n*n keys S₁₍ₙ₊₁₎˜Sₙ₍ₙ₊₁₎ are connected across the column wires P₁˜Pₙ₊₁ and the row wires L₁˜Lₙ correspondingly. Taking the column wire Pₙ₊₁ and the row wire Lₙ as an example, the column wire Pₙ₊₁ is connected to the power supply VCC via a resistor Rₙ₊₁. The row wire Lₙ is connected to a port Kₙ. The key Sₙ₍ₙ₊₁₎ is connected across the row wire Lₙ and the column wire Pₙ₊₁.

The ports K₁˜Kₙ are normally high by connecting to the power supply VCC via the diodes D₁˜Dₙ. The ports K₁˜Kₙ are sequentially set low one at time by the control unit 11 during scanning. When any of the ports K₁˜Kₙ is set low, the corresponding column wire P₁˜Pₙ is changed from high to low.

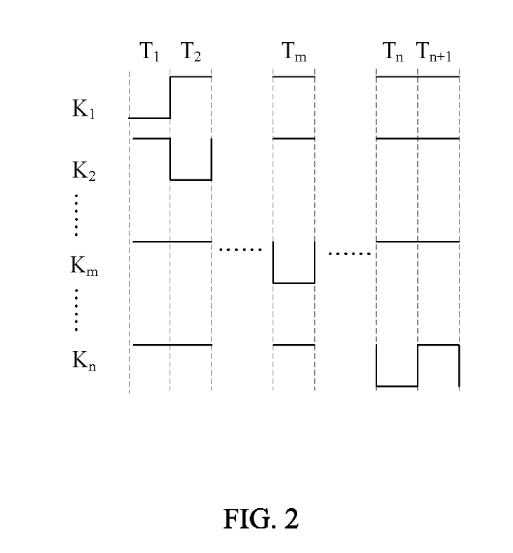

Referring also to FIG. 2, there are a number of scanning sequences T₁ to Tₙ₊₁. During each of the scanning sequences T₁ to Tₙ₊₁, the ports K₁˜Kₙ are normally high and the ground column wire Pₙ₊₁ is always low. Starting with the scanning sequence T₁, the ports K₁˜Kₙ are set low one at a time in sequence. When one of the ports Kₘ is set low, the others of the ports K₁˜Kₙ are normally high. The row wire connected to the low port Kₘ and the corresponding numbered column wire Pₘ is also pulled low. When the scanning sequence counts to Tₙ₊₁, the ports K₁˜Kₙ are all maintained high. When scanning the ports, if any one of the other ports K₁˜Kₙ is low, it is determined a key crossing the row wire connecting to the low one of the other ports and the low column wire is pressed. For example, at the start of scan T₁, the port K₁ is set low, and both the row wire L₁ and the column wire P₁ are pulled to low while the other ports K₂˜Kₙ, the other row wires L₂˜Lₙ, and the other column wire P₂˜Pₙ are set to normally high. The control unit 11 scans the other ports K₂˜Kₙ and finds the port K₃ is low, at which point the control unit 11 determines that the key Sₘ₁ is pressed.

During each scan when one of the ports K₁˜Kₙ is set low and the corresponding row and column wires are pulled low it may happen that a user pressed the corresponding key at the same moment. To avoid missing recognition of the key press, the control unit 11 is programmed to determine which key is pressed only after a whole scanning period T₁ to Tₙ₊₁ expires. In other words, after each scan if one of the other pots is found to be low that information is stored, and once all scans are done, the information checked and a determination of which key was pressed if any is made. For example, during the scanning sequence T₁, the port K₂ is found to be low that the information is stored, when the scanning sequence counts Tₙ₊₁, if the port K₂ is found to be low, then the key S₂₍ₙ₊₁₎ is determined to be pressed. If the port K₂ is found to be high, the key S₂₁ is determined to be pressed.

Therefore, only n ports are used and checked to find out which one of the n*n keys is pressed.

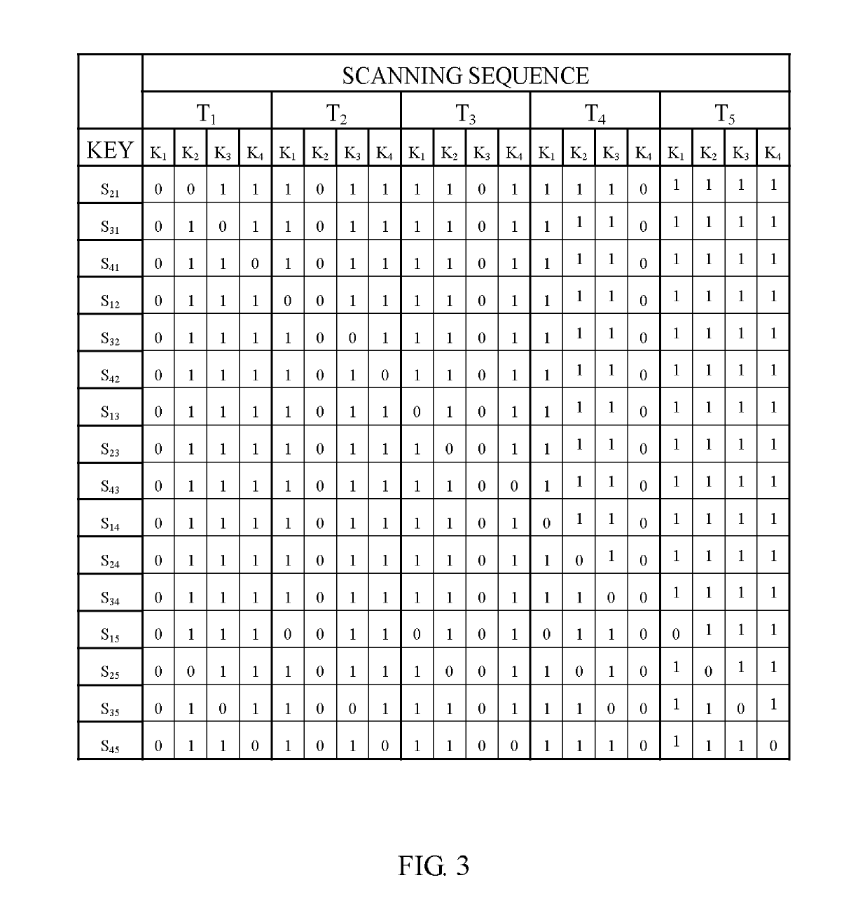

Referring also to FIG. 3, a truth table of the scanning circuit 10 wherein the natural number n equals 4 is shown. The truth table provides 16 statuses of the ports K₁, K₂, K₃, and K₄. During the scanning sequence T₁, if the key S₂₁ is pressed down, the ports K₁, K₂, K₃, and K₄ are found to be low, low, high, and high respectively.

Therefore, just 4 ports K₁, K₂, K₃, and K₄ are needed for a scanning circuit with 16 keys, which occupies fewer ports of a control unit 11 as compared to previous scanning circuit.

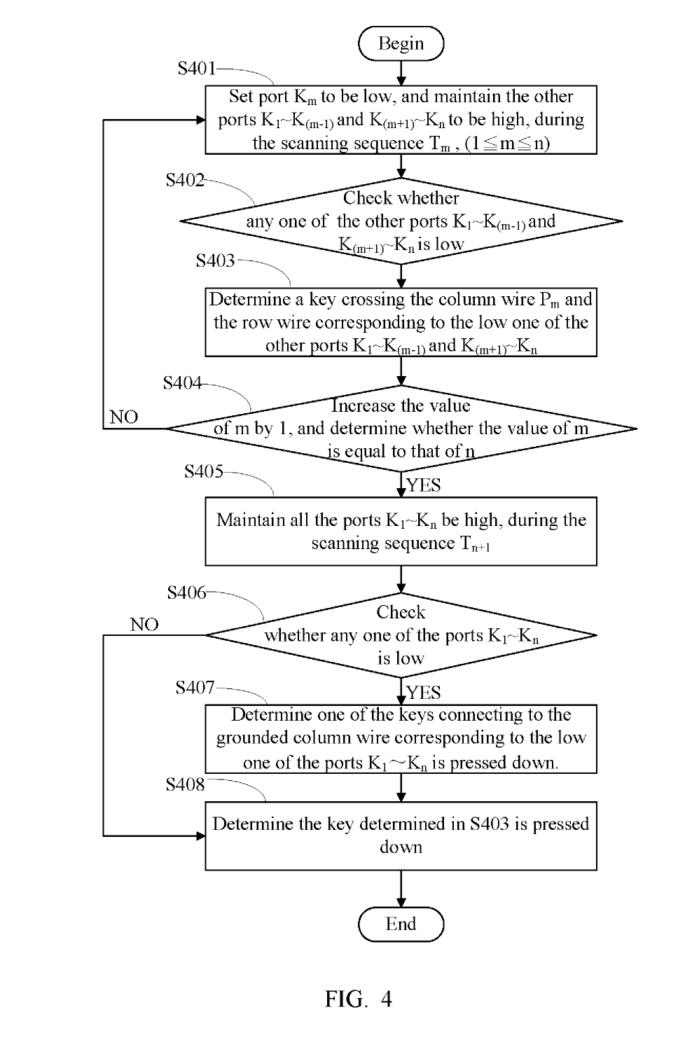

Referring to FIG. 4, a scanning method for scanning a keyboard to find out which keys thereof are pressed is illustrated, the scanning method corresponds to the scanning circuit 10 mentioned above. The procedure includes the following steps.

In step S401, during the scanning sequence Tₘ, setting the port Kₘ to be low, and maintaining the other ports K₁˜K₍ₘ₋₁₎ and K₍ₘ₊₁₎˜Kₙ to be high. Both n and m are natural numbers and m is variable from 1 to n. The row wire Lₘ connected to the low port Kₘ and the column wire Pₘ are also pulled to be low.

In step S402, checking whether any one of the other ports K₁˜K₍ₘ₋₁₎ and K₍ₘ₊₁₎˜Kₙ is low. If any one of the other ports K₁˜K₍ₘ₋₁₎ and K₍ₘ₊₁₎˜Kₙ is low, then the procedure goes to step S403, otherwise, the procedure goes to step S404.

In step S403, determining a key crossing the column wire Pₘ and the row wire corresponding to the low one of the other ports K₁˜K₍ₘ₋₁₎ and K₍ₘ₊₁₎˜Kₙ.

In step S404, increasing the value of m by 1, and determining whether the value of m is equal to that of n. If yes, then the procedure goes to step S405, otherwise, the procedure returns to step S401.

In step S405, maintaining all the ports K₁˜Kₙ to be high, during the scanning sequence Tₙ₊₁.

In step S406, scanning the ports K₁˜Kₙ to find out whether any one of the ports K₁˜Kₙ is low. If one of the ports K₁˜Kₙ is found to be low, the procedure goes to step S407; otherwise, the procedure goes to step S408.

In step S407, determining one of the keys S₁₍ₙ₊₁₎˜Sₙ₍ₙ₊₁₎ connecting to the grounded column wire Pₙ₊₁ corresponding to the low one of the ports K₁˜Kₙ is pressed, then the procedure goes to step S408.

In step S408, determining the key determined in step S403 is pressed, the procedure ends.

It is understood that the present disclosure may be embodied in other forms without departing from the spirit thereof. Thus, the present examples and embodiments are to be considered in all respects as illustrative and not restrictive, and the disclosure is not to be limited to the details given herein.

What is claimed is:

1. A scanning circuit for scanning a keyboard with a plurality of keys, the scanning circuit comprising:
n column wires, wherein n is a natural number greater than zero;
a ground column wire having a terminal for being connected to a high voltage source via a resistive component and another terminal grounded;
n row wires crossing the n column wires and the ground column wire to form a matrix comprising n*(n+1) intersections;
a control unit comprising n ports K₁˜Kₙ electrically connected to the row wires correspondingly;
n diodes set on n intersections of the matrix, wherein each diode has a positive terminal electrically connected to the corresponding row wire, and a negative terminal electrically connected to the corresponding numbered column wire;
n*n keys set on the intersections of the matrix except where the diodes are located, wherein the n*n keys are connected across column wires comprising the n column wires and the ground column wires and the n row wires correspondingly.

2. The scanning circuit as recited in claim 1, wherein each of the column wires and the ground column wire is for being connected to a high voltage source via a resistive component.

3. A scanning method of scanning a keyboard using a scanning circuit as recited in claim 1, comprising:
a. during a scanning sequence Tₘ, setting a port Kₘ in the scanning circuit to be low, and maintaining others ports K₁˜K₍ₘ₋₁₎ and K₍ₘ₊₁₎˜Kₙ in the scanning circuit to be high, wherein both n and m are natural numbers other than zero, m is a variable having an initial value less than n, a row wire Lₘ connected to the low port Kₘ and a column wire Pₘ are also pulled to be low;
b. checking whether any one of the other ports K₁˜K₍ₘ₋₁₎ and K₍ₘ₊₁₎˜Kₙ is low;
c. determining a key crossing the column wire Pₘ and a row wire corresponding to the low one of the other ports K₁˜K₍ₘ₋₁₎ and K₍ₘ₊₁₎˜Kₙ;
d. increasing the value of m by one, and determining whether the value of m is equal to that of n;
e. maintaining all the ports K₁˜Kₙ to be high during a Tₙ₊₁ scanning sequence if the value of m is equal to that of n;
f. scanning the ports K₁˜Kₙ to find out whether any one of the ports K₁˜Kₙ is low;
g. determining one of the keys connecting to the ground column wire corresponding to the low one of the ports K₁˜Kₙ is pressed if one of the ports K₁˜Kₙ is found to be low; and
h. determining the key which is determined in step c is pressed.

4. The scanning method as recited in claim 3, further comprising:
repeating steps a, b, c, and d if the value of m is not equal to that of n.

5. The scanning method as recited in claim 3, further comprising:
going to step h directly if one of the ports K₁˜Kₙ is not found to be low.
